(19) United States
(12) Patent Application Publication
(10) Pub. No.: US 2026/0096485 A1
(43) Pub. Date: Apr. 2, 2026

(54) SEMICONDUCTOR PACKAGE

(71) Applicant: SAMSUNG ELECTRONICS CO., LTD., Suwon-si (KR)

(72) Inventor: JUNGHOON KANG, Suwon-si (KR)

(73) Assignee: SAMSUNG ELECTRONICS CO., LTD., Suwon-si (KR)

(21) Appl. No.: 19/219,520

(22) Filed: May 27, 2025

(30) Foreign Application Priority Data
Oct. 2, 2024 (KR) 10-2024-0134064

(51) Int. Cl. H01L 25/16; G02B 6/42; H01L 23/28; H01L 23/49; H10B 80/00

(52) U.S. Cl. CPC H10W 90/00; G02B 6/4214; G02B 6/4245; H10W 72/50; H10W 74/00; H10B 80/00

(57) ABSTRACT

A semiconductor package includes a substrate, a logic die on the substrate, a base insulating layer on side surfaces and an upper surface of the logic die, an insulating layer through via extending through the base insulating layer at a side of the logic die, a high bandwidth memory on an upper surface of the base insulating layer, at least one optical structure on the upper surface of the base insulating layer, and at least one optical connector including an optical fiber configured to transmit an optical signal between the at least one optical structure and an external device, where the high bandwidth memory includes a plurality of memory dies stacked in a first direction that perpendicular to the upper surface of the base insulating layer and the at least one optical structure is connected to the logic die in the first direction.

### CROSS-REFERENCE TO RELATED APPLICATION

This application is based on and claims priority to Korean Patent Application No. 10-2024-0134064, filed on Oct. 2, 2024, in the Korean Intellectual Property Office, the disclosure of which is incorporated by reference herein in its entirety.

### BACKGROUND

### 1. Field

The present disclosure relates to a semiconductor package.

### 2. Description of Related Art

As technologies such as biohealth, artificial intelligence (Al), virtual reality (VR), autonomous driving, and robots advance, data traffic is increasing exponentially. Accordingly, ultra-high-speed data communications are required, and demands for optical transceivers for communicating with optical signals rather than electrical signals are increasing.

Silicon photonics technology is a technology that implements photonic integrated circuits capable of processing optical signals on silicon chips. The silicon photonics technology has the characteristics of low optical propagation loss, low power consumption, high bandwidth, and compatibility with mature commercial complementary metal-oxide-semiconductor (CMOS) processes. Along with these silicon photonics technologies, silicon photonics-based packaging technologies are also being developed to integrate photonics modules with existing semiconductor packages.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor package that may improve an optical communication speed with an external device and reduce signal loss.

Additional aspects will be set forth in part in the description which follows and, in part, will be apparent from the description, or may be learned by practice of the presented embodiments.

According to an aspect of an example embodiment, a semiconductor package may include a substrate, a logic die on the substrate, a base insulating layer on side surfaces and an upper surface of the logic die, an insulating layer through via extending through the base insulating layer at a side of the logic die, a high bandwidth memory on an upper surface of the base insulating layer, at least one optical structure on the upper surface of the base insulating layer, and at least one optical connector including an optical fiber configured to transmit an optical signal between the at least one optical structure and an external device, where the high bandwidth memory includes a plurality of memory dies stacked in a first direction that perpendicular to the upper surface of the base insulating layer and the at least one optical structure is connected to the logic die in the first direction.

According to an aspect of an example embodiment, a semiconductor package may include a substrate, a logic die on the substrate, a base insulating layer on side surfaces and an upper surface of the logic die, an insulating layer through via extending through the base insulating layer at a side of the logic die, a high bandwidth memory on an upper surface of the base insulating layer, an optical structure on the upper surface of the base insulating layer, and an optical connector including an optical fiber configured to transmit an optical signal between the optical structure and an external device, where the high bandwidth memory includes a plurality of memory dies stacked in a first direction that is perpendicular to the upper surface of the base insulating layer, in plan view, the optical structure overlaps at least a portion of the logic die, and the optical structure is connected to the logic die in the first direction.

According to an aspect of an example embodiment, a semiconductor package may include a substrate, and a plurality of chiplets on the substrate, the plurality of chiplets including a logic die on the substrate, a base insulating layer on side surfaces and an upper surface of the logic die, an insulating layer through via extending through the base insulating layer at a side of the logic die, a high bandwidth memory on an upper surface of the base insulating layer, an optical structure on the upper surface of the base insulating layer, and an optical connector including an optical fiber configured to transmit an optical signal between the optical structure and an external device, where the high bandwidth memory includes a plurality of memory dies stacked in a first direction that is perpendicular to the upper surface of the base insulating layer, and the optical structure is connected to the logic die in the first direction.

### BRIEF DESCRIPTION OF THE DRAWINGS

The above and other aspects, features, and advantages of certain example embodiments of the present disclosure will be more apparent from the following description taken in conjunction with the accompanying drawings, in which:

FIG. 1 is a top plan view of a semiconductor package according to one or more embodiments;

FIG. 2 is a cross-sectional view of a semiconductor package taken along line A-A′ of FIG. 1 according to one or more embodiments;

FIG. 3 is a schematic block diagram showing components of an optical structure according to one or more embodiments;

FIG. 4 is a cross-sectional diagram schematically showing a photonic integrated circuit according to one or more embodiments;

FIG. 5 is a cross-sectional view of a semiconductor package according to one or more embodiments;

FIG. 6 is a cross-sectional view of a semiconductor package according to one or more embodiments;

FIG. 7 is a cross-sectional view of a semiconductor package according to one or more embodiments;

FIG. 8 is a cross-sectional view of a semiconductor package according to one or more embodiments;

FIG. 9 is a cross-sectional view of a semiconductor package according to one or more embodiments;

FIG. 10 is a top plan view of a semiconductor package according to one or more embodiments;

FIG. 11 is a cross-sectional view of a semiconductor package taken along line B-B′ of FIG. 10 according to one or more embodiments;

FIG. 12 is a cross-sectional view of a semiconductor package taken along line B-B′ of FIG. 10 according to one or more embodiments; and

FIG. 13 to FIG. 19 are process cross-sectional views illustrating a manufacturing method for a semiconductor package according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

To clearly describe the present disclosure, parts that are irrelevant to the description are omitted, and like numerals refer to like or similar components throughout the specification.

As used herein, expressions such as “at least one of,” when preceding a list of elements, modify the entire list of elements and do not modify the individual elements of the list. For example, the expression, “at least one of a, b, or c,” should be understood as including only a, only b, only c, both a and b, both a and c, both b and c, or all of a, b, and c.

Further, since sizes and thicknesses of constituent members shown in the accompanying drawings are arbitrarily given for better understanding and ease of description, the present disclosure is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

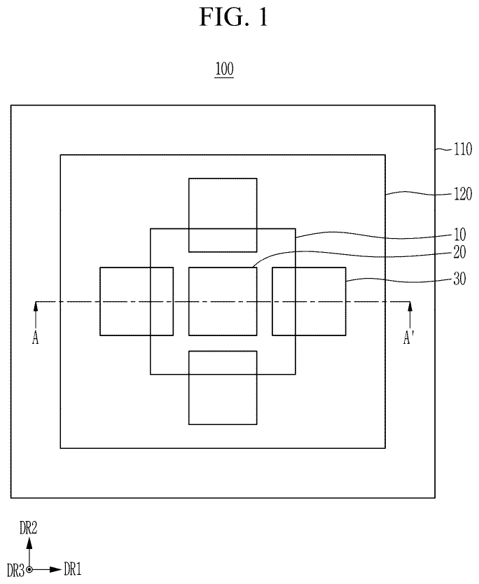

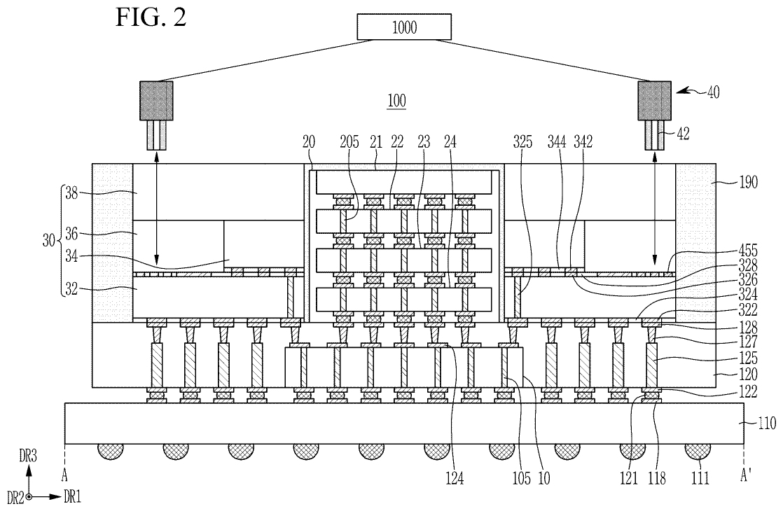

Hereinafter, a semiconductor package according to one or more embodiments will be described with reference to FIG. 1 and FIG. 2.

FIG. 1 is a top plan view of a semiconductor package according to one or more embodiments.

FIG. 2 is a cross-sectional view of a semiconductor package taken along line A-A′ of FIG. 1 according to one or more embodiments.

Referring to FIGS. 1 and 2, the semiconductor package 100 according to one or more embodiments may include a substrate 110, a logic die 10 positioned on the substrate 110, a base insulating layer 120 positioned on a side surface and an upper surface of the logic die 10, an insulating layer through via 125 (i.e., insulating layer through vias) extending through the base insulating layer 120 on opposite sides of the logic die 10, a high-bandwidth memory (HBM) 20 and an optical structure 30 positioned on an upper surface of the base insulating layer 120, and an optical connector 40 including an optical fiber for transmitting an optical signal between the optical structure 30 and an external device.

The substrate 110 may be a substrate for package, e.g., a printed circuit board (PCB) or a ceramic substrate. If the substrate 110 is a PCB, the substrate 110 may be made of at least one material of a phenol resin, an epoxy resin, and polyimide. The substrate 110 may include integrated circuits. The substrate 110 may include one or more routing wires.

The substrate 110 may include a first surface and a second surface facing each other. Each of the first surface and the second surface may be aligned in a first direction DR1 and a second direction DR2. The second direction DR2 may intersect with the first direction DR1. For example, the second direction DR2 may be perpendicular to the first direction DR1. The first side and the second side may face each other along a third direction DR3. The third direction DR3 may be a direction perpendicular to the first direction DR1 and the second direction DR2.

A plurality of first connection pads 118 may be positioned on a first surface of the substrate 110, and a plurality of external connection members 111 may be positioned on a second surface of the substrate 110. The external connection members 111 may electrically connect the semiconductor package 100 to an external device (e.g., a main board).

The external connection members 111 may include a conductive material. For example, the external connection members 111 may include a metal such as copper, aluminum, or an alloy thereof. For example, the external connection members 111 may be solder balls.

A plurality of first connection pads 118 may electrically connect components positioned on a first surface of the substrate 110 to the substrate 110. The logic die 10 and the base insulating layer 120 may be positioned on the first surface of the substrate 110. A plurality of second connection pads 122 may be positioned on a lower surface of the logic die 10 and a lower surface of the base insulating layer 120. Some of the second connection pads 122 may be positioned on the lower surface of the logic die 10, and others may be positioned on the lower surface of the base insulating layer 120. The second connection pads 122 may be connected to the first connection pads 118. For example, the second connection pads 122 may be connected to the first connection pads 118 by the first connection members 121. Each of the first connection members 121 may be positioned between a lower surface of each of the second connection pads 122 and an upper surface of each of the first connection pads 118.

Each of the first connection pads 118, the second connection pads 122, and the first connection members 121 may include a conductive material. For example, each of the first connection pads 118, the second connection pads 122, and the first connection members 121 may include a metal such as copper, aluminum, or an alloy thereof. For example, the external connection members 121 may be solder balls.

The logic die 10 may have an upper surface and side surfaces covered by the base insulating layer 120. The lower surface of the logic die 10 may be positioned at substantially a same level as that of the lower surface of the base insulating layer 120. The logic die 10 may be positioned at a central portion of the base insulating layer 120 in a plan view. The logic die 10 may be surrounded by the base insulating layer 120.

The logic die 10 may be connected to a high bandwidth memory 20 and an optical structure 30. The logic die 10 may generate an electrical signal to control the high bandwidth memory 20 and transmit it to the high bandwidth memory 20. The logic die 10 may read data from the high bandwidth memory 20, or may write data to the high bandwidth memory 20. The logic die 10 may process data read from the high bandwidth memory 20. The logic die 10 may generate an electrical signal to control the optical structure 30, and may transmit it to the optical structure 30. The logic die 10 may process an electrical signal received from the optical structure 30.

For example, the logic die 10 may include an application specific integrated circuit (ASIC), a central processing unit (CPU), a graphic processing unit (GPU), or a field programmable gate array (FPGA).

A plurality of third connection pads 124 may be positioned on the upper surface of the logic die 10. Some of the third connection pads 124 may be connected to the high bandwidth memory 20, and others may be connected to the optical structure 30.

A plurality of logic through vias 105 may be provided to extend through the logic die 10. The logic through vias 105 may extend in a third direction DR3 through the logic die 10. Signals may be transmitted between the high bandwidth memory 20 and the substrate 110, and between the optical structure 30 and the substrate 110 through logic through vias 105.

The logic through vias 105 may include a conductive material. For example, the logic through vias 105 may include a metal such as copper, aluminum, or an alloy thereof.

The base insulating layer 120 may cover the side and upper surfaces of the logic die 10. The base insulating layer 120 may be positioned on opposite sides of the logic die 10 in a cross-sectional view. A plurality of insulating layer through vias 125 extending through the base insulating layer 120 may be provided. The insulating layer through vias 125 may extend through the base insulating layer 120 at opposite sides of the logic die 10. The insulating layer through vias 125 may extend in the third direction DR3. A signal may be transmitted between the optical structure 30 and the substrate 110 through the insulating layer through vias 125.

The base insulating layer 120 may be positioned on upper surfaces of the insulating layer through vias 125 and upper surfaces of the third connection pads 124. A plurality of fourth connection pads 128 may be positioned on the upper surface of the base insulating layer 120. Side and lower surfaces of the fourth connection pads 128 may be covered by the base insulating layer 120. The upper surfaces of the fourth connection pads 128 may be positioned at substantially a same level as that of the upper surface of the base insulating layer 120. The fourth connection pads 128 may be embedded in the upper surface of the base insulating layer 120.

The base insulating layer 120 may include an insulating material. For example, the base insulating layer 120 may include a silicon oxide (SiOₓ), a silicon nitride (SiNₓ), a silicon oxynitride (SiONₓ), or a combination thereof, but embodiments are not limited thereto. The insulating layer through vias 125 may include a conductive material. For example, the insulating layer through vias 125 may include a metal such as copper, aluminum, or an alloy thereof.

Some of the fourth connection pads 128 may be connected to the insulating layer through vias 125, and others may be connected to the third connection pads 124. The fourth connection pads 128 may be connected by the insulating layer through vias 125 and the third connection pads 124 and a plurality of connection vias 127. The connection vias 127 may extend in the third direction DR3. Side surfaces of the connection vias 127 may be surrounded by the base insulating layer 120. Some of the connection vias 127 may connect between lower surfaces of the fourth connection pads 128 and upper surfaces of the insulating layer through vias 125 in the third direction DR3. Other portions of the connection vias 127 may connect in the third direction DR3 between the lower surfaces of the fourth connection pads 128 and the upper surfaces of the third connection pads 124.

Each of the third connection pads 124, the fourth connection pads 128, and the connection vias 127 may include a conductive material. For example, the third connection pads 124, the fourth connection pads 128, and the connection vias 127 may each include a metal such as copper, aluminum, or an alloy thereof.

The high bandwidth memory 20 may be positioned on the upper surface of the base insulating layer 120 and the upper surfaces of the plurality of fourth connection pads 128. The high bandwidth memory 20 may be electrically connected to some of the fourth connection pads 128 connected to the logic die 10. The high bandwidth memory 20 and the logic die 10 may be electrically connected through the fourth connection pads 128. The high bandwidth memory 20 may be positioned on the central portion of the base insulating layer 120 in a plan view. The high bandwidth memory 20 may be vertically above the logic die 10 in the third direction DR3. The high bandwidth memory 20 may be positioned on the central portion of the logic die 10.

The high bandwidth memory 20 may include multiple memory dies 21, 22, 23, and 24. The memory dies 21, 22, 23, and 24 may be stacked in a direction perpendicular to the upper surface of the base insulating layer 120 (e.g., in the third direction DR3). For example, each of the memory dies 21, 22, 23, and 24 may be, but is not necessarily limited to, a dynamic random access memory (DRAM).

In an embodiment, the high bandwidth memory 20 may include a memory die, and may not include a buffer die. That is, the high bandwidth memory 20 according to one or more embodiments may be a bufferless-HBM. The high bandwidth memory 20 may be electrically connected to the logic die 10, so the logic die 10 may be utilized as a buffer die without including a separate buffer die.

A plurality of memory through vias 205 may be provided to extend through memory dies 21, 22, 23, and 24. The memory through vias 205 may extend in the third direction DR3 through the memory dies 21, 22, 23, and 24. Signals may be transferred between the memory dies 21, 22, 23, and 24 and between the memory dies 21, 22, 23, and the logic die 10 through the memory through vias 205. The memory dies 21, 22, 23, and 24 may transmit data together through the memory through vias 205, thereby improving bandwidth. The signal transmission distance may be shortened by the memory through vias 205, which may reduce power consumption.

The memory dies 21, 22, 23, and 24 may be connected via a plurality of solder bumps, and may be molded by a molding member. For example, a MR (mass reflow)-MUF (molded underfill) method may be used, in which solder is melted through a reflow process before molding to bond the memory dies, and then underfill and molding are performed at the same time, but embodiments are not limited thereto. As another example, a TC (thermo compression)-non-conductive film (NCF) method may be used, which inserts an NCF between memory dies, applies heat and pressure to bond them, and then performs molding.

The optical structure 30 may be positioned on the upper surface of the base insulating layer 120 and the upper surfaces of the plurality of fourth connection pads 128. The optical structure 30 may be electrically connected to some of the fourth connection pads 128 connected to the insulating layer through vias 125. The optical structure 30 may be electrically connected to the insulating layer through via 125 through the fourth connection pads 128. A plurality of fifth connection pads 322 may be positioned on the lower surface of the optical structure 30. A first insulating layer 324 may be positioned between the fifth connection pads 322. A side surface of each of the fifth connection pads 322 may be surrounded by the first insulating layer 324. The fifth connection pads 322 may be separated by the first insulating layer 324. Lower surfaces of the fifth connection pads 322 may be in contact with upper surfaces of the fourth connection pads 128, and a lower surface of the first insulating layer 324 may contact the upper surface of the base insulating layer 120.

The fifth connection pads 322 may include a conductive material. For example, the fifth connection pads 322 may include a metal such as copper, aluminum, or an alloy thereof. The first insulating layer 324 may include an insulating material. For example, the first insulating layer 324 may include a silicon oxide (SiOₓ), a silicon nitride (SiNₓ), a silicon oxynitride (SiONₓ), or a combination thereof, but embodiments are not limited thereto.

That is, the optical structure 30 may be bonded on the base insulating layer 120 using a hybrid copper bonding (HCB) method, but embodiments are not limited thereto. A manner in which the optical structure 30 is bonded onto the base insulating layer 120 may be varied in various ways.

The optical structure 30 may be positioned on an edge of the base insulating layer 120 in a plan view. The optical structure 30 may overlap at least a portion of the logic die 10 in the third direction DR3. The optical structure 30 may be positioned on an edge of the logic die 10 in a plan view. The optical structure 30 may overlap the insulating layer through vias 125 in the third direction DR3.

The optical structure 30 may be positioned along a direction parallel to upper surfaces of the high bandwidth memory 20 and the base insulating layer 120 (e.g., the first direction DR1 or the second direction DR2). The optical structure 30 may be positioned along a direction perpendicular to upper surfaces of the logic die 10 and the base insulating layer 120 (e.g., the third direction DR3). The optical structure 30 may be connected to the logic die 10 in a direction perpendicular to the upper surface of the logic die 10 (e.g., in the third direction DR3). For example, the optical structure 30 may be connected to the logic die 10 through the fourth connection pads 128, the connection vias 127, and the third connection pads 124, but embodiments are not limited thereto. Accordingly, the signal transmission path between the optical structure 30 and the logic die 10 may be shortened compared to a comparative example in which the optical structure 30 is positioned on first surfaces of the logic die 10 and the substrate 110 in a direction parallel to the first surfaces, thereby enabling high-speed communication and reducing signal loss.

The optical structure 30 may be separated from the first surface of the substrate 110 by the base insulating layer 120. The optical structure 30 may be connected to the substrate 110 in a direction perpendicular to the first surface of the substrate 110 (e.g., in the third direction DR3) through the insulating layer through vias 125. For example, the optical structure 30 may be connected to the substrate 110 through the fourth connection pads 128, the connection vias 127, the insulating layer through vias 125, the second connection pads 122, the first connection member 121, and the first connection pads 118, but embodiments are not limited thereto.

A plurality of optical structures 30 may be provided, and the optical structures 30 may be arranged on the upper surface of the base insulating layer 120 with the high bandwidth memory 20 provided therebetween. As illustrated, the optical structures 30 may be arranged at opposite sides of the high bandwidth memory 20, but embodiments are not limited thereto.

The optical structure 30 may include a photonic integrated circuit 32 and an electronic integrated circuit 34. The photonic integrated circuit 32 may be positioned on the upper surface of the base insulating layer 120. The photonic integrated circuit 32 may also be positioned on the fourth connection pads 128. The electronic integrated circuit 34 may be positioned on at least a portion of an upper surface of the photonic integrated circuit 32. In one or more embodiments, the photonic integrated circuit 32 and the electronic integrated circuit 34 may overlap the logic die 10 in the third direction DR3. The photonic integrated circuit 32 and the electronic integrated circuit 34 may overlap an edge portion of the logic die 10 in the third direction DR3. The photonic integrated circuit 32 may be positioned on a region of the upper surface of the base insulating layer 120 that overlaps the edge portion of the logic die 10 in the third direction DR3. The electronic integrated circuit 34 may be positioned on a region of an upper surface of the photonic integrated circuit 32 that overlaps the edge portion of the logic die 10 in the third direction DR3.

A lower surface of the optical structure 30 may be the lower surface of the photonic integrated circuit 32. The fifth connection pads 322 and the first insulating layer 324 surrounding the fifth connection pads 322 may be positioned on a lower surface of the photonic integrated circuit 32. The photonic integrated circuit 32 may be electrically connected to the logic die 10 and the insulating layer through vias 125 through the fifth connection pads 322. The photonic integrated circuit 32 may be electrically connected to the substrate 110 through the insulating layer through vias 125.

A plurality of sixth connection pads 326 may be positioned on an upper surface of the photonic integrated circuit 32. A second insulating layer 328 may be positioned between the sixth connection pads 326. A side surface of each of the sixth connection pads 326 may be surrounded by the second insulating layer 328. The sixth connection pads 326 may be separated by the second insulating layer 328.

A plurality of seventh connection pads 342 may be positioned on a lower surface of the electronic integrated circuit 34. A third insulating layer 344 may be positioned between the seventh connection pads 342. A side surface of each of the seventh connection pads 342 may be surrounded by the third insulating layer 344. The seventh connection pads 342 may be separated by the third insulating layer 344. Lower surfaces of the seventh connection pads 342 may contact upper surfaces of the sixth connection pads 326, and a lower surface of the third insulating layer 344 may contact the upper surface of the second insulating layer 328.

Each of the sixth connection pads 326 and the seventh connection pads 342 may include a conductive material. For example, each of the sixth connection pads 326 and the seventh connection pads 342 may include a metal such as copper, aluminum, or an alloy thereof. Each of the second insulating layer 328 and the third insulating layer 344 may include an insulating material. For example, the second insulating layer 328 and the third insulating layer 344 may each include a silicon oxide (SiOₓ), a silicon nitride (SiNₓ), a silicon oxynitride (SiONₓ), or a combination thereof, but embodiments are not limited thereto.

That is, the electronic integrated circuit 34 may be bonded on the photonic integrated circuit 32 in the HCB manner, but embodiments are not necessarily limited thereto. A manner in which the electronic integrated circuit 34 is bonded onto the photonic integrated circuit 32 may be varied in various ways.

As described above, as the photonic integrated circuit 32 and the electronic integrated circuit 34 are bonded, the photonic integrated circuit 32 and the electronic integrated circuit 34 may be electrically connected.

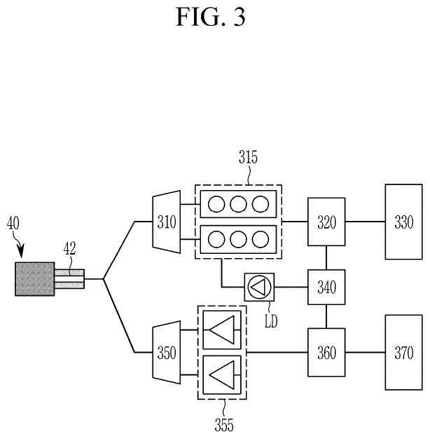

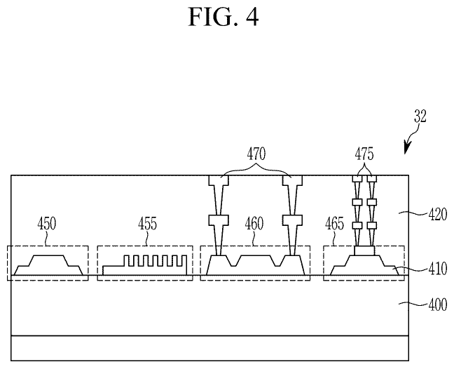

For example, the photonic integrated circuit 32 may convert an optical signal received from an optical fiber 42 into an electrical signal to transmit it to the electronic integrated circuit 34, and the electronic integrated circuit 34 may convert or amplify an electrical signal received from the photonic integrated circuit 32 to transmit it to the logic die 10. The electronic integrated circuit 34 may transmit an electrical signal received from the logic die 10 to the photonic integrated circuit 32, and the photonic integrated circuit 32 may convert and modulate the electrical signal received from the electronic integrated circuit 34 into an optical signal to transmit it to the optical fiber 42. This will be described in more detail with reference to FIG. 3 and FIG. 4.

A photonic layer through via 325 extending through the photonic integrated circuit 32 may be provided. The photonic layer through via 325 may extend in the third direction DR3 through the photonic integrated circuit 32. The photonic layer through via 325 may be connected between the fifth connection pads 322 and the sixth connection pads 326. The electronic integrated circuit 34 may be electrically connected to the logic die 10 and the insulating layer through vias 125 through the photonic layer through via 325. The electronic integrated circuit 34 may be electrically connected to the substrate 110 through the photonic layer through via 325 and the insulating layer through via 125.

In FIG. 2, one photonic layer through via 325 is illustrated, but embodiments are not limited thereto, and a plurality of photonic layer through vias 325 may be provided.

The photonic layer through via 325 may include a conductive material. For example, the photonic layer through vias 325 may include a metal such as copper, aluminum, or an alloy thereof.

The photonic integrated circuit 32 may include a grating coupler 455 optically connected to an optical fiber. The grating coupler 455 may serve to transmit an optical signal received through an optical fiber in a different direction. For example, the grating coupler 455 may transmit an optical signal received in a vertical direction toward an upper surface of the photonic integrated circuit 32 in a horizontal direction parallel to the upper surface of the photonic integrated circuit 32. The grating coupler 455 may transmit an optical signal generated from the photonic integrated circuit 32 to an optical fiber.

The grating coupler 455 may be covered by the second insulating layer 328. In FIG. 2, the second insulating layer 328 is illustrated as covering a side surface of the grating coupler 455, but embodiments are not limited thereto, and the second insulating layer 328) may further cover an upper surface of the grating coupler 455. When the second insulating layer 328 covers the upper surface of the grating coupler 455, the second insulating layer 328 may include a light-transmitting material. For example, the second insulating layer 328 may include a silicon oxide, a silicon nitride, a silicon oxynitride, or a combination thereof.

The grating coupler 455 may not overlap the electronic integrated circuit 34 in the third direction DR3. That is, the electronic integrated circuit 34 may not be positioned between the grating coupler 455 and the optical connector 40 in the third direction DR3.

In one or more embodiments, the optical structure 30 may include a light-transmitting insulating layer 36 positioned on upper surface of the photonic integrated circuit 32 and a side surface of the electronic integrated circuit 34. In one or more embodiments, the electronic integrated circuit 34 may be positioned on a portion of the upper surface of the photonic integrated circuit 32. The light-transmitting insulating layer 36 may be positioned on another portion of the upper surface of the photonic integrated circuit 32. The light-transmitting insulating layer 36 may cover an upper surface of the grating coupler 455 and an upper surface of the second insulating layer 328. The light-transmitting insulating layer 36 may include a light-transmitting material. For example, the light-transmitting insulating layer 36 may include a silicon oxide, a silicon nitride, a silicon oxynitride, or a combination thereof. The light-transmitting insulating layer 36 may be formed as a single layer or multiple layers.

As illustrated in FIG. 2, the light-transmitting insulating layer 36 may contact the upper surface of the second insulating layer 328. In one or more embodiments, the light-transmitting insulating layer 36 and the second insulating layer 328 may include a same material. When the light-transmitting insulating layer 36 and the second insulating layer 328 include the same material, an interface between the light-transmitting insulating layer 36 and the second insulating layer 328 may not be identified.

In FIG. 2, the upper surface of the light transmitting insulating layer 36 is illustrated as being positioned at substantially the same level as that of the upper surface of the electronic integrated circuit 34, but embodiments are not limited thereto. For example, the light-transmitting insulating layer 36 may be positioned further on an upper surface of the electronic integrated circuit 34.

In one or more embodiments, the optical structure 30 may include a cover layer 38 on the upper surface of the electronic integrated circuit 34. The cover layer 38 may cover the upper surface of the photonic integrated circuit 32 and the upper surface of the electronic integrated circuit 34. The cover layer 38 may come into contact with the upper surface of the electronic integrated circuit 34. The cover layer 38 may be spaced apart from the upper surface of the photonic integrated circuit 32 in the third direction DR3. In the third direction DR3, the light-transmitting insulating layer 36 may be positioned between the cover layer 38 and the photonic integrated circuit 32. The cover layer 38 may be positioned on the upper surface of the light-transmitting insulating layer 36. The cover layer 38 may contact the upper surface of the light-transmitting insulating layer 36.

The cover layer 38 may include a light-transmitting material. For example, the cover layer 38 may include, but is not necessarily limited to, glass or silicon (Si).

The optical connector 40 may be positioned on the upper surface of the cover layer 38. The optical connector 40 may include an optical fiber 42. In FIG. 2, for convenience, the optical connector 40 is illustrated as including one optical fiber 42, but the optical connector 40 may include a plurality of optical fibers 42, and the optical fibers 42 may be provided in an array form.

The cover layer 38 may be positioned between an end portion of the optical fiber 42 of the optical connector 40 and the upper surface of the photonic integrated circuit 32. The cover layer 38 may serve to protect the photonic integrated circuit 32 and the electronic integrated circuit 34 while transmitting light between the optical connector 40 and the photonic integrated circuit 32.

The optical connector 40 may be positioned such that the end portion of the optical fiber 42 faces the upper surface of the cover layer 38. The end portion of the optical fiber 42 may be spaced from the upper surface of the cover layer 38. An air gap can be positioned between the end portion of the optical fiber 42 and the upper surface of the cover layer 38.

The optical connector 40 may be connected through a hole provided in a frame covering the semiconductor package 100. For example, the optical connector 40 and the hole may be coupled to each other in a male-female structure.

A plurality of optical connectors 40 may be provided, and the optical connectors 40 may be respectively connected between the optical structures 30 and an external device 1000. A first end of the optical fiber 42 of each of the optical connectors 40 may be optically connected to each of the optical structures 30, and a second end of the optical fiber 42 of each of the optical connectors 40 may be optically connected to an external device 1000.

The semiconductor package 100 may include a first molding member 190 that molds the high bandwidth memory 20 and the optical structure 30 on an upper surface of the base insulating layer 120. The first molding member 190 may cover upper surface and side surfaces of the high bandwidth memory 20. The first molding member 190 may cover a side surface of the optical structure 30. The first molding member 190 may not cover the upper surface of the optical structure 30. That is, the upper surface of the cover layer 38 may not be covered by the first molding member 190, and may be exposed. The upper surface of the first molding member 190 may be positioned at substantially the same level as that of the upper surface of the cover layer 38. The first molding member 190 may include e.g., an epoxy molding compound (EMC), but embodiments are not limited thereto.

The semiconductor package 100 is not limited to the components described above, and may include other components. According to one or more embodiments, the semiconductor package 100 may include a front-side redistribution layer between a lower surface of the logic die 10 and an upper surface of the substrate 110, or may include a back-side redistribution layer between an upper surface of the logic die 10 and a lower surface of the high bandwidth memory 20 and a lower surface of the optical structure 30, or may include both a front-side redistribution layer and a back-side redistribution layer.

Hereinafter, optical components and electronic components of the optical structure 30 of FIGS. 1 and 2 will be described with reference to FIG. 3 and FIG. 4.

FIG. 3 is a schematic block diagram showing components of an optical structure according to one or more embodiments. FIG. 4 is a cross-sectional diagram schematically showing a photonic integrated circuit according to one or more embodimentsphotonic integrated circuit.

In one or more embodiments, the photonic integrated circuit 32 may include optical components, and the electronic integrated circuit 34 may include electron components. The electronic components of the electronic integrated circuit 34 may be formed of a transistor array, and the optical components of the photonic integrated circuit 32 may include a portion of the transistor array.

For example, the photonic integrated circuit 32 may include, but is not limited to, a multiplexer (MUX) 310, a plurality of optical modulators 315, a demultiplexer (DEMUX) 350, and a plurality of optical detectors 355, and may further include other components. For example, an electronic integrated circuit 34 may include a current-voltage converter 360, an output driver 370, an input buffer 330, a modulator driver 320, but embodiments are not limited thereto, and a controller 340 may further include other components. The current-voltage converter 360, the output driver 370, the input buffer 330, the modulator driver 320, and the controller 340 may be classified according to a function performed by each component.

The optical connector 40 may be an input and output port for an optical signal between the optical fiber 42 connected to an external device and the semiconductor package 100. Hereinafter, each component will be described separately for a case of receiving an optical signal through the optical fiber 42 and a case of transmitting an optical signal.

Referring to FIG. 3, an optical signal received through the optical connector 40 may reach multiple photodetectors 355 through the demultiplexer 350. The photodetector 355 may convert an optical signal into an analog electrical signal. The current-voltage converter 360 may convert a current signal output from the photodetector 355 into a voltage signal. For example, the current-voltage converter 360 may amplify a current output of the photodetector 355 of the photonic integrated circuit 32 or another type of sensor to a usable voltage. The converted electrical signal may be output to the outside of the optical structure 30 (e.g., the logic die 10) through the output driver 370.

When an electrical signal is received in the input buffer 330, based on the received electrical signal, a light source element emits light, and the modulator driver 320 may drive the optical modulators 315 to modulate the light emitted from the light source element. Electronic components may operate under the control of the controller 340. The modulated light may be transmitted to the optical connector 40 through the multiplexer 310, and the optical signal may be transmitted through the optical fiber 42 connected to the optical connector 40.

Referring to FIG. 4, the photonic integrated circuit 32 may include a buried oxide layer (BOX) 400, a silicon layer 410 positioned on the buried oxide layer 400, and a clad layer 420 positioned on the silicon layer 410.

The buried oxide layer 400 may be positioned on a silicon-based member. The buried oxide layer 400 may be formed on an entire upper surface of the silicon-based member, or may be formed only on a portion thereof.

The silicon layer 410 may be positioned on the buried oxide layer 400. The silicon layer 410 may include optical components. In one or more embodiments, the silicon layer 410 may include an optical waveguide 450, a grating coupler 455, an optical modulator 460, and a photodetector 465.

For example, a silicon material layer may be formed on the buried oxide layer 400, and the silicon layer 410 may be formed by extending through the silicon material layer through a lithography process and an etching process. The patterned silicon layer 410 may include optical components. A clad layer 420 may be stacked over the patterned silicon layer 410. A nitride layer may be further positioned on the patterned silicon layer 410.

The optical connector 40 may be optically connected to other optical components. The optical waveguide 450 may implement an optical path that confines and transmits light within the photonic integrated circuit 32. The optical waveguide 450 may be formed to include a single structure or a plurality of structures. For example, the optical waveguide 450 may include an optical fiber, a silicon waveguide member, a silicon nitride waveguide member, etc.

The grating coupler 455 may be a medium that receives an optical signal transmitted from an external device through the optical fiber 42 or transmits an optical signal to an external device through the optical fiber 42. In one or more embodiments, the grating coupler 455 may be used as a medium for transmitting and receiving optical signals by the photonic integrated circuit 32, but it will be understood by those of ordinary skill in the art that an edge coupler may be used as a medium for transmitting and receiving optical signals of the photonic integrated circuit 32. When the grating coupler 455 is used, the optical signal may be transmitted and received vertically through the upper surface of the photonic integrated circuit 32, and when the edge coupler is used, the optical signal may be transmitted and received horizontally through a side surface (or edge) of the photonic integrated circuit 32.

The optical modulator 460 may convert light emitted from a light source element into an optical signal containing information by modulating the light according to a signal to be transmitted. The optical modulator 460 may be a phase modulator, for example. In one or more embodiments, the optical modulator 460 may be, but is not limited to, one of a Mach-Zehnder modulator, a micro-ring modulator, an electro-absorption modulator, and a LN/Si hybrid and thin-film lithium niobate (TFLN) modulator.

A photodetector 465 may generate and output an electrical signal according to the received optical signal. The photodetector 465 may be, e.g., a positive-intrinsinc-negative (PIN) structure including a germanium (Ge) region. The photonic integrated circuit 32 may further include a ring resonator. The ring resonator may be a device that filters a signal of a desired wavelength from an optical signal transmitted through the optical waveguide 450.

The embodiments described herein are not limited to the optical components described above, and the photonic integrated circuit 32 may further include a switch, a splitter, a heater, etc. in addition to the components described above.

The optical components may be classified into passive components and active components. The optical waveguide 450 and the grating coupler 455 may belong to the passive components, and the optical modulator 460 and the photodetector 465 may belong to the active components. To electrically connect the active components to the electronic components, they may be electrically connected to contact terminals 470 and 475 that extend the clad layer 420 and are exposed on an upper surface thereof. The sixth connection pads 326 of FIG. 2 may be illustrated for connection pads exposed on an upper surface of the clad layer 420 among the contact terminals 470 and 475. The second insulating layer 328 of FIG. 2 may be illustrated for a portion of the clad layer 420. The contact terminals 470 and 475 may have various structures for electrically connecting the active components to the electronic components of the electronic integrated circuit 34, and are not limited to a structure of the contact terminals 470 and 475 illustrated in FIG. 4.

FIG. 4 illustrates a schematic structure of optical components according to one or more embodiments, and the optical components are not limited to the structure illustrated in FIG. 4.

The semiconductor package 100 according to one or more embodiments may include the base insulating layer 120 covering side and upper surfaces of the logic die 10, the insulating layer through vias 125 extending through the base insulating layer 120 positioned on opposite sides of the logic die 10, the high bandwidth memory 20 positioned on an upper surface of the base insulating layer 120, and the optical structure 30. The high bandwidth memory 20 and the optical structure 30 may be connected with the logic die 10 in a direction perpendicular to an upper surface of the logic die 10. Accordingly, the signal transmission path between the optical structure 30 and the logic die 10 may be shortened compared to a comparative example in which the optical structure 30 is positioned on first surfaces of the logic die 10 and the substrate 110 in a direction parallel to the first surfaces, thereby enabling high-speed communication and reducing signal loss.

The optical structure 30 of the semiconductor package 100 according to one or more embodiments may overlap the logic die 10 in a plan view. Accordingly, a size of the semiconductor package 100 may be reduced compared to a comparative example in which the optical structure 30 is positioned on the first surface of the logic die 10 and the substrate 110 along a direction parallel to the first surface.

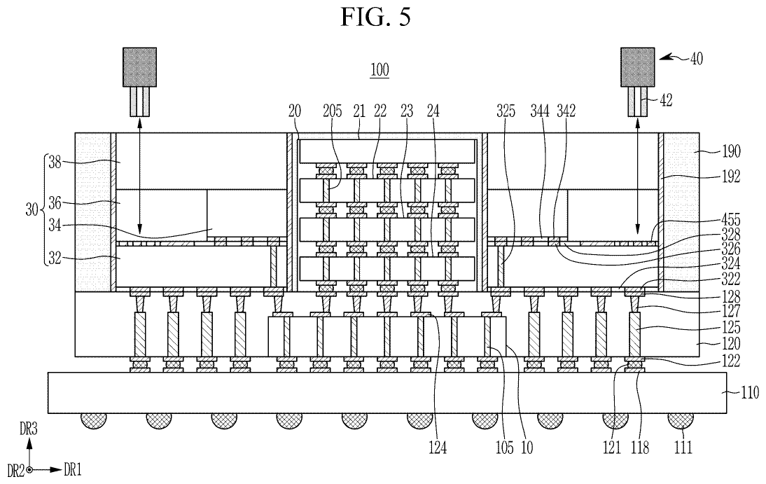

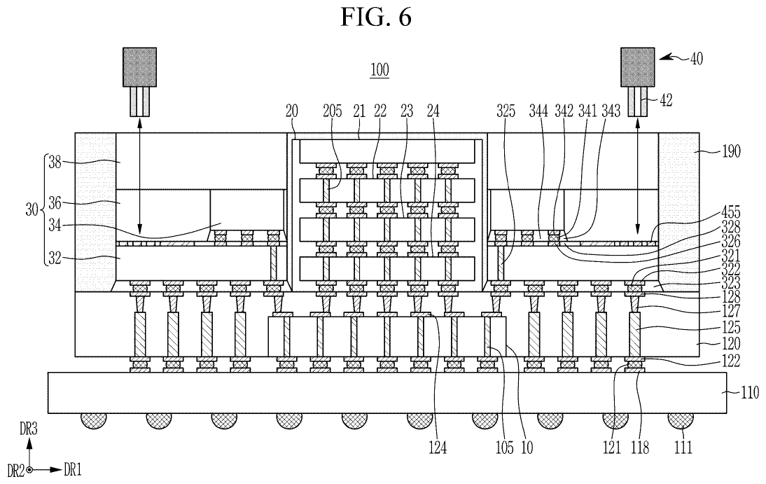

Hereinafter, a modified example of the semiconductor package 100 of FIGS. 1 to 4 will be described with each of FIG. 5 and FIG. 6.

FIG. 5 is a cross-sectional view of a semiconductor package according to one or more embodiments. FIG. 6 is a cross-sectional view of a semiconductor package according to one or more embodiments. Description of aspects that are the same as or similar to those described above may be omitted.

In FIG. 5, a molding structure of the optical structure 30 may be somewhat different from those described above. In the embodiment illustrated in FIG. 5, a bonding structure of the optical structure 30 may be partially different from those described above.

Referring to FIG. 5, the semiconductor package 100 may further include a second molding member 192 positioned between a side surface of the optical structure 30 and the first molding member 190. The second molding member 192 may cover the side surface of the optical structure 30. The second molding member 192 may not cover an upper surface of the optical structure 30. An upper surface of the second molding member 192 may be positioned at substantially a same level as that of the upper surface of the optical structure 30. The upper surface of the second molding member 192 may be positioned at substantially a same level as that of the upper surface of the cover layer 38.

The first molding member 190 may cover upper and side surfaces of the high bandwidth memory 20 and the side surface of the second molding member 192. The first molding member 190 may be separated from the side surface of the optical structure 30 by the second molding member 192. The first molding member 190 may not cover the upper surface of the second molding member 192 and the upper surface of the optical structure 30. An upper surface of the first molding member 190 may be positioned at substantially a same level as the upper surface of the second molding member 192 and the upper surface of the optical structure 30. The upper surface of the first molding member 190 may be positioned at substantially the same level as that of the upper surface of the cover layer 38.

In one or more embodiments, the optical structure 30 may be first molded with the second molding member 192 and then molded together with the high bandwidth memory 20 with the first molding member 190. That is, the optical structure 30 may be double molded.

The second molding member 192 may include a same material as that of the first molding member 190, or may include a different material from that of the first molding member 190. For example, the second molding member 192 may include, but is not limited to, EMC.

Referring to FIG. 6, the semiconductor package 100 may include a first underfill member 323 positioned between the lower surface of the optical structure 30 and the upper surface of the base insulating layer 120. In FIG. 6, the first underfill member 323 may be added as a bonding method of the optical structure 30 is different from the embodiments of FIGS. 1 to 4.

In FIGS. 1 to 4, the fifth connection pads 322 may contact the fourth connection pads 128, and the first insulating layer 324 may be in contact with the base insulating layer 120. That is, the optical structure 30 may be bonded on the base insulating layer 120 in an HCB manner. In contrast, in FIG. 6, the fifth connection pads 322 may be electrically connected to the fourth connection pads 128 by the second connection members 321. The second connection members 321 may be solder bumps, for example. That is, the optical structure 30 may be bonded on the base insulating layer 120 using solder bumps.

In one or more embodiments, the semiconductor package 100 may include the second connection members 321 each positioned on lower surfaces of the fifth connection pads 322. The first underfill member 323 may surround the side surfaces of the fifth connection pads 322 and the side surfaces of the second connection members 321. The first underfill member 323 may fill a remaining space between a lower surface of the photonic integrated circuit 32 and an upper surface of the base insulating layer 120. The first underfill member 323 may fill a space between the second connection members 321. The first underfill member 323 may prevent adjacent second connection members 321 from being short-circuited.

In one or more embodiments, the semiconductor package 100 may include the third connection members 341 each positioned on lower surfaces of the seventh connection pads 342. The seventh connection pads 342 may be electrically connected to the sixth connection pads 326 by the third connection members 341. The third connection members 341 may be solder bumps, for example. That is, the electronic integrated circuit 34 may be bonded on the photonic integrated circuit 32 using solder bumps.

In one or more embodiments, the semiconductor package 100 may include a second underfill member 343 positioned between the lower surface of the electronic integrated circuit 34 and the upper surface of the photonic integrated circuit 32. The second underfill member 343 may surround the side surfaces of the seventh connection pads 342 and the side surfaces of the third connection members 341. The second underfill member 343 may fill a remaining space between the lower surface of the electronic integrated circuit 34 and the upper surface of the photonic integrated circuit 32. The second underfill member 343 may fill a space between the third connection members 341. The second underfill member 343 may prevent adjacent third connection members 341 from being short-circuited.

In FIG. 6, it is illustrated that both the electronic integrated circuit 34 and the photonic integrated circuit 32, and the photonic integrated circuit 32 and the base insulating layer 120 may be bonded with solder bumps, but embodiments are not limited thereto. For example, the electronic integrated circuit 34 and the photonic integrated circuit 32 may be bonded using HCB, and the photonic integrated circuit 32 and the base insulating layer 120 may be bonded using solder bumps, etc., in different ways.

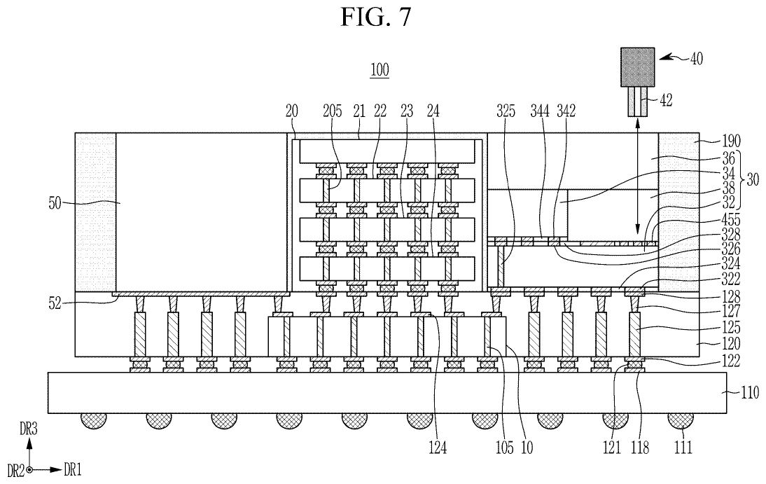

Hereinafter, a modified example of the semiconductor package 100 of FIGS. 1 to 4 will be described with reference to FIG. 7.

FIG. 7 is a cross-sectional view of a semiconductor package according to one or more embodiments. Description of aspects that are the same as or similar to those described above may be omitted. FIG. 7 may differ from the others described above in some respects in that a thermal conduction block 50 is added.

Referring to FIG. 7, the semiconductor package 100 may further include a thermal conduction pad 52 positioned on an upper surface of the base insulating layer 120, and the thermal conduction block 50 positioned on the thermal conduction pad 52 and positioned in a direction parallel to the optical structure 30. The thermal conduction pad 52 may be connected to the insulating layer through via 125 and the logic die 10. A lower surface of the thermal conduction block 50 may be in contact with an upper surface of the thermal conduction pad 52. The upper surface of the thermal conduction block 50 may be exposed, and may not be covered by the first molding member 190. The thermal conduction pad 52 and the thermal conduction block 50 may serve to release or disperse heat generated from the logic die 10 and the substrate 110 to the outside.

In one or more embodiments, the thermal conduction pad 52 may overlap the insulating layer through via 125 and the logic die 10 in a direction perpendicular to the upper surface of the base insulating layer 120 (e.g., in the third direction DR3). The thermal conduction pad 52 may be connected to the insulating layer through via 125 and the logic die 10 in the third direction DR3. Accordingly, a distance between the substrate 110 and the logic die 10, and the thermal conduction pad 52 may be shortened, thereby transferring heat to the thermal conduction block 50 more quickly, and improving heat dissipation performance.

The thermal conduction pad 52 may include a thermal interface material (TIM). For example, the TIM may include, but is not limited to, a metal with high thermal conductivity, such as copper or aluminum.

The thermal conduction block 50 may include a material having high thermal conductivity. The thermal conduction block 50 may include, but is not limited to, a metal such as copper or aluminum, or a ceramic.

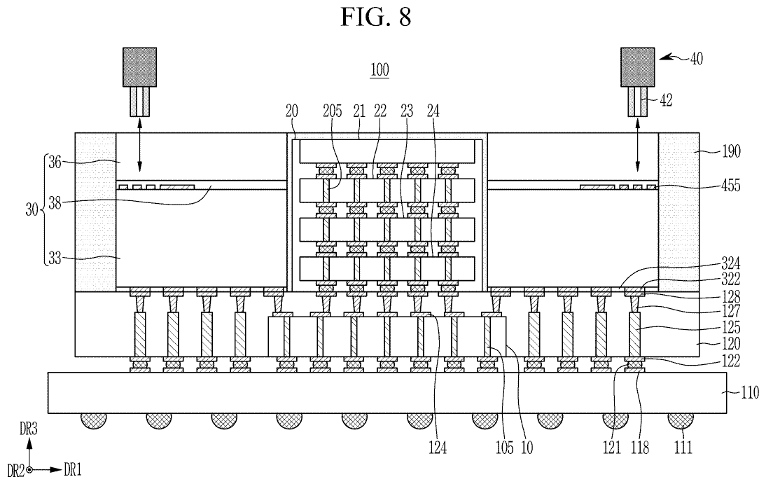

Hereinafter, a modified example of the semiconductor package 100 of FIGS. 1 to 4 will be described with reference to FIG. 8.

FIG. 8 is a cross-sectional view of a semiconductor package according to one or more embodiments. Description of aspects that are the same as or similar to those described above may be omitted. In FIG. 8, a configuration of the optical structure 30 may be partially different from those described above.

Referring to FIG. 8, the optical structure 30 may include a photoelectronic integrated circuit 33 positioned on an upper surface of the base insulating layer 120, a cover layer 38 covering an upper surface of the photoelectronic integrated circuit 33, and a light-transmitting insulating layer 36 positioned between the photoelectronic integrated circuit 33 and the cover layer 38. The cover layer 38 and the light-transmitting insulating layer 36 may include a light-transmitting material.

In the embodiments of FIG. 1 to FIG. 4, the photonic integrated circuit 32 and the electronic integrated circuit 34 may be functionally and structurally separated. In contrast, in FIG. 8, the photonic integrated circuit 32 and the electronic integrated circuit 34 may be functionally and structurally integrated to be implemented as the photoelectronic integrated circuit 33. The photoelectronic integrated circuit 33 may convert an optical signal received from the optical fiber 42 into an electrical signal to transmit it to the logic die 10, and may convert an electrical signal received from the logic die 10 into an optical signal to transmit it to the optical fiber 42. The photoelectronic integrated circuit 33 may include a grating coupler 455 optically connected to the optical fiber 42. The photoelectronic integrated circuit 33 may receive a signal, received through the optical fiber 42, through the grating coupler 455, and may transmit an optical signal generated in the photoelectronic integrated circuit 33 to the optical fiber 42 through the grating coupler 455.

In FIGS. 1 to 4, the electronic integrated circuit 34 may cover a portion of the upper surface of the photonic integrated circuit 32, so the light-transmitting insulating layer 36 may cover only a remaining portion of the photonic integrated circuit 32. On the other hand, in FIG. 8, the light-transmitting insulating layer 36 may completely cover an upper surface of the photoelectronic integrated circuit 33.

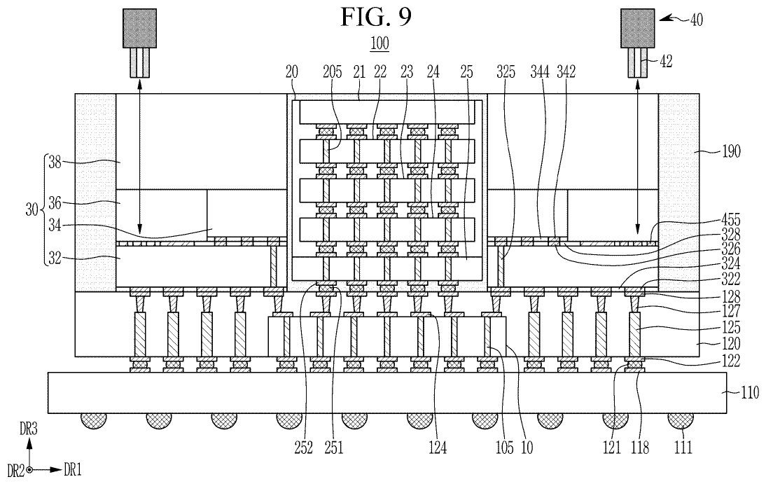

Hereinafter, a modified example of the semiconductor package 100 of FIGS. 1 to 4 will be described with reference to FIG. 9.

FIG. 9 is a cross-sectional view of a semiconductor package according to one or more embodiments. Description of aspects that are the same as or similar to those described above may be omitted. In FIG. 9, a configuration of the high bandwidth memory 20 may be partially different from those described above.

Referring to FIG. 9, the high bandwidth memory 20 may further include a base die 25 below the memory dies 21, 22, 23, and 24. The base die 25 may have a larger planar area than that of the memory dies 21, 22, 23, and 24. The base die 25 may serve to support the memory dies 21, 22, 23, and 24. The memory dies 21, 22, 23, and 24 may be stacked on an upper surface of the base die 25. The memory dies 21, 22, 23, and 24 may be molded on the upper surface of the base die 25. The molding member of the high bandwidth memory 20 may cover upper and side surfaces of the memory dies 21, 22, 23, and 24 and the upper surface of the base die 25. A side surface of the base die 25 may not be covered by a molding member of the high bandwidth memory 20.

According to one or more embodiments, the base die 25 may be a heterogeneous die with the memory dies 21, 22, 23, and 24. For example, the base die 25 may be a field programmable gate array (FPGA) die. For example, the FPGA die may include a computation circuit, and may perform arithmetic or logical operations on data read from the memory dies 21, 22, 23, and 24. In this case, the high bandwidth memory 20 may perform some data processing within the memory without communicating with the logic die 10. The high bandwidth memory 20 may support processing in memory (PIM).

As another example, the base die 25 may be a cache memory die. The cache memory die may provide faster data access than the memory dies 21, 22, 23, and 24. The cache memory die may store data frequently used in the logic die 10. The cache memory die may serve as a buffer between the logic die 10 and the memory dies 21, 22, 23, and 24. For example, each of the memory dies 21, 22, 23, and 24 may be a DRAM die, and the base die 25 may be a static random access memory (SRAM) die.

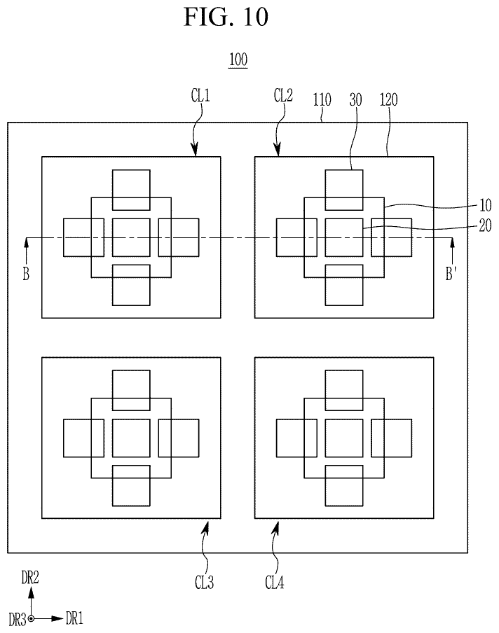

Hereinafter, a modified example of the semiconductor package 100 of FIGS. 1 to 4 will be described with reference to FIG. 10 to FIG. 12.

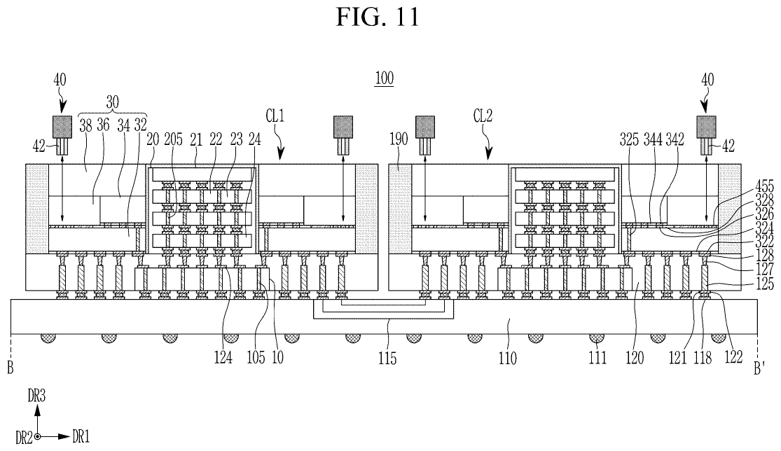

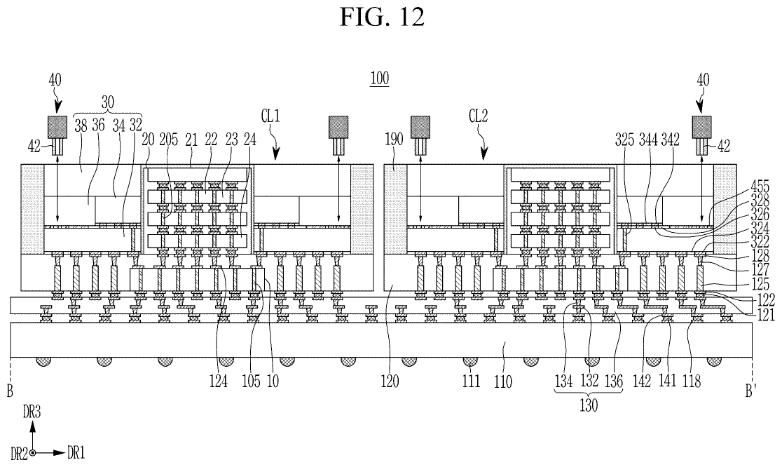

FIG. 10 is a top plan view of a semiconductor package according to one or more embodiments. FIG. 11 is a cross-sectional view of a semiconductor package taken along line B-B′ of FIG. 10 according to one or more embodiments. FIG. 12 is a cross-sectional view of a semiconductor package taken along line B-B′ of FIG. 10 according to one or more embodiments. Description of aspects that are the same as or similar to those described above may be omitted. FIGS. 10 to 12 may differ from those above in providing a plurality of chiplets CL1, CL2, CL3, and CL4 having the structure in FIGS. 1 to 4.

First, referring to FIGS. 10 and 11, the semiconductor package 100 may include a substrate 110 and the chiplets CL1, CL2, CL3, and CL4 mounted on the substrate 110. According to one or more embodiments, each of the chiplets CL1, CL2, CL3, and CL4 may include same components and have a same structure as those of the semiconductor package 100 of FIGS. 1 to 4. Each of the chiplets CL1, CL2, CL3, and CL4 may include a logic die 10 positioned on a first surface of the substrate 110, a base insulating layer 120 positioned on a side surface and an upper surface of the logic die 10, insulating layer through vias 125 extending through the base insulating layer 120 at opposite sides of the logic die 10, a high bandwidth memory 20 and an optical structure 30 positioned on an upper surface of the base insulating layer 120, and an optical connector 40 including an optical fiber 42 for transmitting an optical signal between the optical structure 30 and an external device. The high bandwidth memory 20 may include a plurality of memory dies 21, 22, 23, and 24 stacked in a vertical direction on an upper surface of the base insulating layer 120. The optical structure 30 may be connected with the logic die 10 in a direction perpendicular to an upper surface of the logic die 10.

In FIGS. 1 to 4, one module is illustrated in which the high bandwidth memory 20 including the memory dies 21, 22, 23, and 24 are vertically stacked on the logic die 10, but embodiments are not limited thereto. As in FIGS. 10 and 11, the semiconductor package 100 may include multiple modules in which the high bandwidth memory 20 including the memory dies 21, 22, 23, and 24 are vertically stacked on the logic die 10. In this case, each of the multiple modules may be called a chiplet. The logic die 10 of each of the chiplets CL1, CL2, CL3, and CL4 may include different functions among various functions of the logic die 10 of FIGS. 1 to 4. That is, various functions of the logic die 10 of FIGS. 1 to 4 may be shared by the multiple chiplets CL1, CL2, CL3, and CL4. Accordingly, the logic die 10 of each of the chiplets CL1, CL2, CL3, and CL4 may be smaller in size than the logic die 10 of FIGS. 1 to 4.

In one or more embodiments, the semiconductor package 100 may further include a bridge layer 115 embedded in an upper portion of the substrate 110. The chiplets CL1, CL2, CL3, and CL4 may be connected by a bridge layer 115. The bridge layer 115 may be positioned between the chiplets CL1, CL2, CL3, and CL4 in a plan view. The bridge layer 115 may, e.g., include silicon, and may include wires patterned into a silicon layer. The chiplets CL1, CL2, CL3, and CL4 may be electrically connected to each other by the bridge layer 115. The logic die 10 of each of the chiplets CL1, CL2, CL3, and Cl4 may communicate through the bridge layer 115. The logic die 10 of the chiplets CL1, CL2, CL3, and Cl4 may access the high bandwidth memory 20 included in different chiplets through the bridge layer 115.

In FIG. 11, one bridge layer 115 is illustrated, but embodiments are not limited thereto. A plurality of bridge layers 115 may be embedded in the substrate 110. For example, the bridge layers 115 may each be positioned between two adjacent chiplets among the chiplets CL1, CL2, CL3, and CL4.

Referring to FIGS. 10 and 12, the semiconductor package 100 may further include a redistribution layer 130 positioned between the substrate 110 and the logic die 10 of each of the chiplets CL1, CL2, CL3, and CL4. In an embodiment, the chiplets CL1, CL2, CL3, and CL4 may be connected by the redistribution layer 130. The redistribution layer 130 may include a redistribution layer 132, a redistribution via 134 connecting the redistribution layer 132 in a direction perpendicular to a first surface of the substrate 110 (e.g., a third direction DR3), and a redistribution insulating layer (136) surrounding the redistribution layer 132 and the redistribution via 134. A plurality of second connection pads 122 positioned on the lower surface of each of the chiplets CL1, CL2, CL3, and CL4 may be connected to the redistribution layer 132 of an uppermost layer of the redistribution layer 130 by a plurality of first connection members 121. The chiplets CL1, CL2, CL3, and CL4 may be electrically connected to each other by the redistribution layer 130.

In one or more embodiments, a plurality of eighth connection pads 142 may be positioned on the lower surface of the redistribution layer 130, and a plurality of fourth connection members 141 may be positioned on the lower surfaces of the eighth connection pads 142, respectively. The eighth connection pads 142 may be connected to the first connection pads 118 positioned on the upper surface of the substrate 110 by the fourth connection members 141. Each of the chiplets CL1, CL2, CL3, and CL4 may be electrically connected to the substrate 110 by the redistribution layer 130.

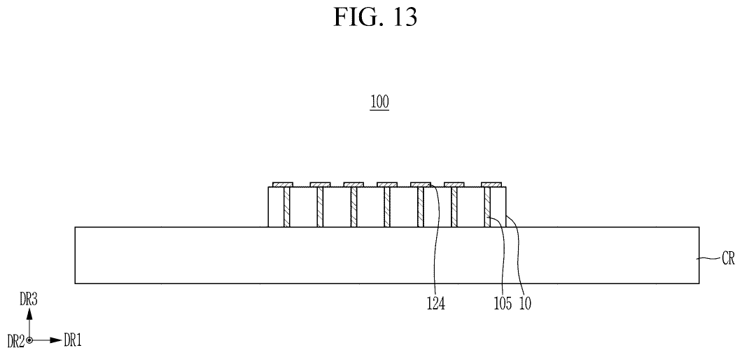

Hereinafter, a manufacturing method of the semiconductor package 100 of FIGS. 1 to 4 will be described with reference to FIG. 13 to FIG. 19.

FIG. 13 to FIG. 19 are process cross-sectional views illustrating a manufacturing method for a semiconductor package according to one or more embodiments.

Referring to FIG. 13, the logic die 10 may be provided on the upper surface of a carrier substrate CR. The logic die 10 may include a plurality of logic through vias 105 that extend through the logic die 10 in a direction perpendicular to the upper surface of the carrier substrate CR (e.g., in the third direction DR3). A plurality of third connection pads 124 may be positioned on the upper surface of the logic die 10. The logic through vias 105 may be connected to a plurality of third connection pads 124.

Each of the logic through vias 105 and the third connection pads 124 may include a metal such as copper or aluminum, but the present disclosure is not necessarily limited thereto.

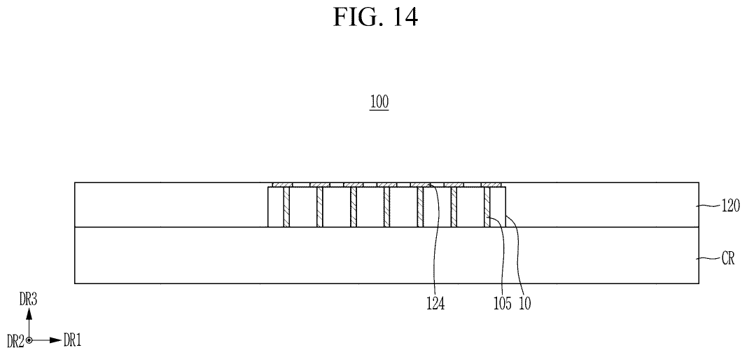

Referring to FIG. 14, an insulating material may be deposited on the carrier substrate CR to form the base insulating layer 120 covering side and upper surfaces of the logic die 10. The base insulating layer 120 may be formed through a chemical vapor deposition (CVD) process or a physical vapor deposition (PVD) process, but embodiments are not limited thereto. The base insulating layer 120 may surround the side surfaces of the third connection pads 124 positioned on the upper surface of the logic die 10.

The base insulating layer 120 may include, e.g., a silicon oxide, a silicon nitride, a silicon oxynitride, or a combination thereof.

For example, after depositing an insulating material to cover the upper surfaces of the third connection pads 124, the upper surfaces of the third connection pads 124 may be exposed through a planarization process. The planarization process may include, e.g., a chemical mechanical polishing (CMP) process. An upper surface of the base insulating layer 120 may be positioned at substantially a same level as the upper surfaces of the third connection pads 124.

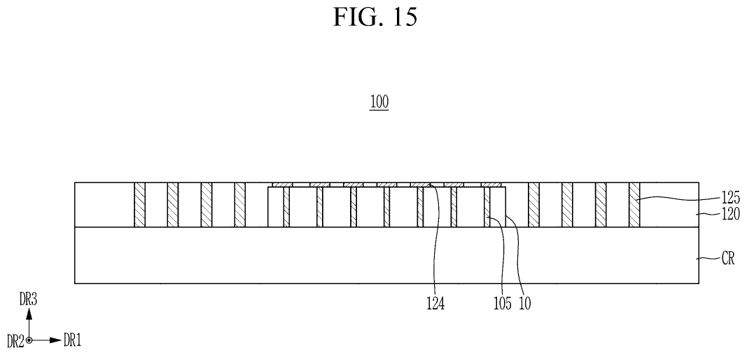

Referring to FIG. 15, a plurality of insulating layer through vias 125 extending through the base insulating layer 120 may be formed. For example, a plurality of through holes extending through the base insulating layer 120 in a direction perpendicular to the upper surface of the carrier substrate CR (e.g., in the third direction DR3) may be formed through a photolithography process and an etching process. Next, the insulating layer through vias 125 may be formed by filling a conductive material inside the through holes. The insulating layer through vias 125 may include a metal such as copper or aluminum, but embodiments are not limited thereto. The insulating layer through vias 125 may be formed through a plating process or a CVD process, but embodiments are not limited thereto.

The insulating layer through vias 125 may extend in the third direction DR3 through the base insulating layer 120 at opposite sides of the logic die 10. Upper surfaces of the insulating layer through vias 125 may be positioned at substantially a same level as the upper surfaces of the third connection pads 124.

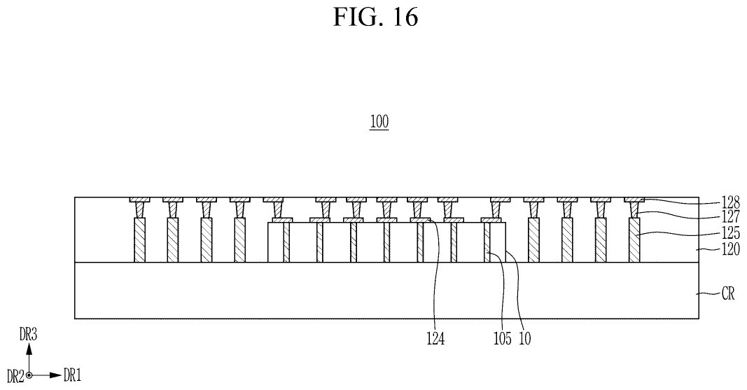

Referring to FIG. 16, an insulating material may be additionally deposited to form the base insulating layer 120 covering upper surfaces of the third connection pads 124 and the insulating layer through vias 125. Next, a plurality of connection vias 127 and a plurality of fourth connection pads 128 may be formed. For example, after patterning the additionally deposited base insulating layer 120 to form a plurality of via holes, a conductive material layer may be formed to fill the inside of the via holes and cover the upper surface of the base insulating layer 120, and the conductive material layer may be patterned to form the connection vias 127 and the fourth connection pads 128.

Each of the connection vias 127 and the fourth connection pads 128 may include a metal such as copper or aluminum, but embodiments are not necessarily limited thereto. The conductive material layer may be formed through a plating process or a CVD process, but embodiments are not limited thereto. The conductive material layer may be patterned through a photolithography process and an etching process.

Next, an insulating material may be additionally deposited to form the base insulating layer 120 covering the side surfaces of the fourth connection pads 128. For example, an insulating material may be additionally deposited to cover the upper surfaces of the fourth connection pads 128, and then the upper surfaces of the fourth connection pads 128 may be exposed through a planarization process. An upper surface of the base insulating layer 120 may be positioned at substantially a same level as the upper surfaces of the fourth connection pads 128.

Some of the connection vias 127 may be connected to the third connection pads 124, and others may be connected to the insulating layer through vias 125. The fourth connection pads 128 may be connected to the third connection pads 124 and the insulating layer through vias 125 by the connection vias 127. Some of the fourth connection pads 128 may be connected to the third connection pads 124, and others may be connected to the insulating layer through vias 125. Connecting to the third connection pads 124 may indicate connecting to the logic die 10.

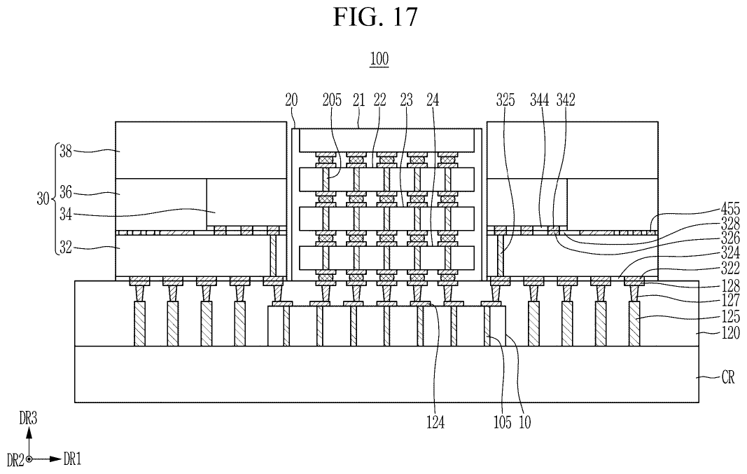

Referring to FIG. 17, the high bandwidth memory 20 and the optical structure 30 may be bonded to the base insulating layer 120 and the fourth connection pads 128. For example, the high bandwidth memory 20 and the optical structure 30 may be bonded in various ways, such as bonded using solder bumps or bonded in the HCB manner without bumps.

In one or more embodiments, the high bandwidth memory 20 and the optical structure 30 may overlap the logic die 10 in the third direction DR3. The high bandwidth memory 20 may overlap a central portion of the logic die 10 in the third direction DR3. The optical structure 30 may overlap an edge portion of the logic die 10 in the third direction DR3. The optical structure 30 may overlap the insulating layer through vias 125 in the third direction DR3.

In one or more embodiments, the high bandwidth memory 20 and the optical structure 30 may be connected to the logic die 10 in the third direction DR3. The high bandwidth memory 20 may be connected to a central portion of an upper surface of the logic die 10 in the third direction DR3. The optical structure 30 may be connected to an edge portion of the upper surface of the logic die 10 in the third direction DR3. The optical structure 30 may be connected with the insulating layer through vias 125 in the third direction DR3.

According to one or more embodiments, a signal transmission path between the optical structure 30 and the logic die 10 and a signal transmission path between the high bandwidth memory 20 and the logic die 10 may be shorter than in a comparative example in which the high bandwidth memory 20 and the optical structure 30 are arranged in a horizontal direction (e.g., in the first direction DR1) with respect to the logic die 10, so that a communication speed of the semiconductor package may be improved and signal loss during communication may be reduced.

In one or more embodiments, the optical structure 30 may be positioned along a direction parallel to upper surfaces of the high bandwidth memory 20 and the base insulating layer 120 (e.g., the first direction DR1 or the second direction DR2). In one or more embodiments, a plurality of optical structures 30 may be provided, and the optical structures 30 may be arranged in a direction parallel to the upper surface of the base insulating layer 120 (e.g., first direction DR1 or second direction DR2). For example, the optical structures 30 may be positioned at opposite sides of the high bandwidth memory 20, but embodiments are not limited thereto.

The high bandwidth memory 20 may include a plurality of memory dies 21, 22, 23, and 24 stacked in a vertical direction (e.g., the third direction DR3). For example, each of the memory dies 21, 22, 23, and 24 may be, but is not necessarily limited to, a DRAM.

In one or more embodiments, the high bandwidth memory 20 may include a memory die, and may not include a buffer die. That is, the high bandwidth memory 20 according to one or more embodiments may be a bufferless-HBM. The high bandwidth memory 20 may be electrically connected to the logic die 10, so that the logic die 10 may be utilized as a buffer die.

The high bandwidth memory 20 may include a plurality of memory through vias 205 extending through the memory dies 21, 22, 23, and 24. A signal transmission path between the memory dies 21, 22, 23, and 24 and the logic die 10 may be shortened and a bandwidth can be increased by the memory penetration vias 205.

In one or more embodiments, the optical structure 30 may include a photonic integrated circuit 32, an electronic integrated circuit 34 positioned on the photonic integrated circuit 32, and a cover layer positioned on an upper surface of the electronic integrated circuit 34. The photonic integrated circuit 32 may be positioned on the upper surface of the base insulating layer 120 and the upper surfaces of the plurality of fourth connection pads 128. The electronic integrated circuit 34 may be positioned on at least a portion of an upper surface of the photonic integrated circuit 32. In one or more embodiments, the photonic integrated circuit 32 and the electronic integrated circuit 34 may overlap the logic die 10 in the third direction DR3. The photonic integrated circuit 32 and the electronic integrated circuit 34 may overlap an edge portion of the logic die 10 in the third direction DR3. The photonic integrated circuit 32 may be positioned on a region of the upper surface of the base insulating layer 120 that overlaps the edge portion of the logic die 10 in the third direction DR3. The electronic integrated circuit 34 may be positioned on a region of an upper surface of the photonic integrated circuit 32 that overlaps the edge portion of the logic die 10 in the third direction DR3.

The photonic integrated circuit 32 may include a grating coupler 455 in a region that is not covered by the electronic integrated circuit 34. The grating coupler 455 may serve to transmit an optical signal received through an optical fiber in a different direction. For example, the grating coupler 455 may transmit an optical signal received in a vertical direction toward an upper surface of the photonic integrated circuit 32 in a horizontal direction parallel to the upper surface of the photonic integrated circuit 32. The grating coupler 455 may transmit an optical signal generated from the photonic integrated circuit 32 to an optical fiber.

A lower surface of the optical structure 30 may be the lower surface of the photonic integrated circuit 32. The photonic integrated circuit 32 may be electrically connected to the logic die 10 and the insulating layer through vias 125 through the fifth connection pads 322 positioned on the lower surface of the photonic integrated circuit 32. The photonic integrated circuit 32 may be electrically connected to the substrate 110 through the insulating layer through vias 125.

In one or more embodiments, the cover layer 38 may cover the upper surface of the photonic integrated circuit 32 and the upper surface of the electronic integrated circuit 34. The cover layer 38 may come into contact with the upper surface of the electronic integrated circuit 34. The cover layer 38 may be spaced apart from the upper surface of the photonic integrated circuit 32 in the third direction DR3. The optical structure 30 may include a light transmitting insulating layer 36 positioned between the cover layer 38 and the photonic integrated circuit 32 in the third direction DR3. The light transmitting insulating layer 36 may be positioned on the upper surface of the photonic integrated circuit 32 and the side surface of the electronic integrated circuit 34. The cover layer 38 may be positioned on the upper surface of the light-transmitting insulating layer 36. The cover layer 38 may be in contact with the upper surface of the light-transmitting insulating layer 36.

The cover layer 38 and he light-transmitting insulating layer 36 may include a light-transmitting material. For example, the cover layer 38 may include, but is not necessarily limited to, glass or silicon (Si). For example, the light-transmitting insulating layer 36 may include a silicon oxide, a silicon nitride, a silicon oxynitride, or a combination thereof.

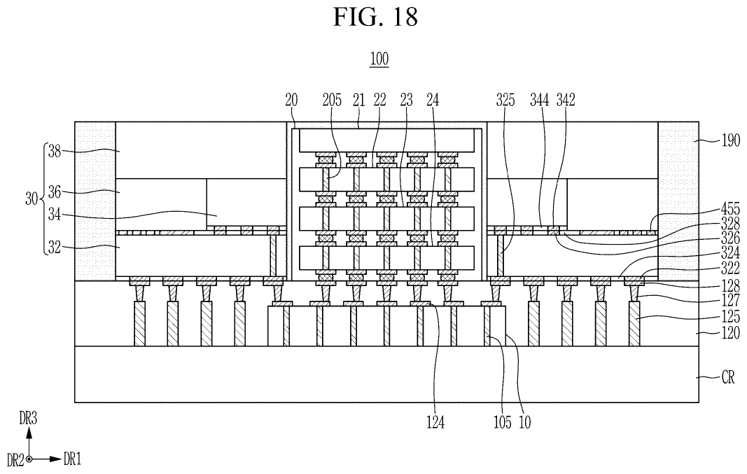

Referring to FIG. 18, the high bandwidth memory 20 and the optical structure 30 may be molded on the upper surface of the base insulating layer 120 with the first molding member 190. A process of molding with the first molding member 190 may include, but is not limited to, a compression molding or transfer molding process, for example. The first molding member 190 may include e.g., an epoxy molding compound (EMC), but embodiments are not limited thereto.

Next, the first molding member 190 may be planarized. The planarization process may include, e.g., a CMP process, but embodiments are not limited thereto. The first molding member 190 may cover upper surface and side surfaces of the high bandwidth memory 20. The first molding member 190 may cover a side surface of the optical structure 30. The first molding member 190 may not cover the upper surface of the optical structure 30. That is, the upper surface of the cover layer 38 may not be covered by the first molding member 190, and may be exposed. The upper surface of the first molding member 190 may be positioned at substantially the same level as that of the upper surface of the cover layer 38.

In FIG. 18, it is illustrated that the optical structure 30 is molded together with the high bandwidth memory 20 into the first molding member 190 at once without separate molding for the optical structure 30, but embodiments are not limited thereto. For example, after the optical structure 30 is first molded, the optical structure 30 may be molded once more together with the high bandwidth memory 20. Furthermore, molding may be performed after underfilling the lower side of the optical structure 30 depending on a manner in which the optical structure 30 is bonded on the base insulating layer 120 and the fourth connection pads 128.

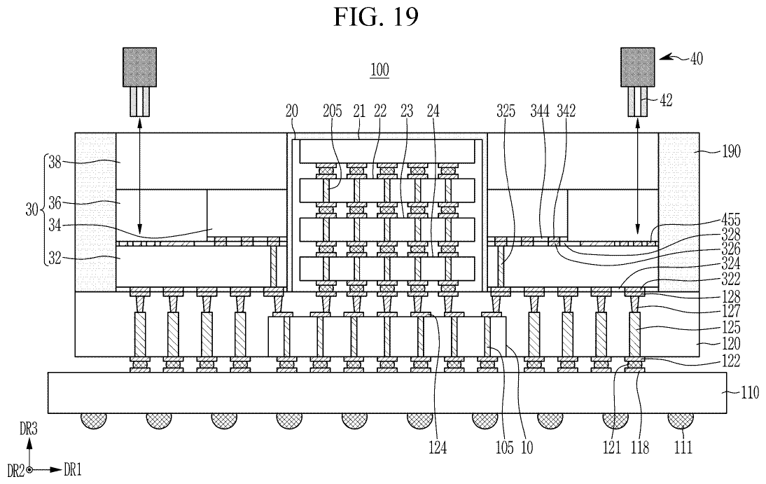

Referring to FIG. 19, the carrier substrate CR is removed, and a plurality of second connection pads 122 and a plurality of first connection members 121 may be formed on the lower surface of the base insulating layer 120 and the lower surface of the logic die 10, and then the first connection members 121 may be bonded on the substrate 110.

Next, an optical connector 40 may be optically connected to the optical structure 30. A frame covering the semiconductor package 100 may be included. The optical connector 40 may be connected through a hole provided in a frame covering the semiconductor package 100. For example, the optical connector 40 and the hole may be coupled to each other in a male-female structure.

The optical connector 40 may be positioned on the upper surface of the cover layer 38. The optical connector 40 may include an optical fiber 42. The optical connector 40 may be positioned such that the end portion of the optical fiber 42 faces the upper surface of the cover layer 38. The end portion of the optical fiber 42 may be spaced from the upper surface of the cover layer 38. An air gap can be positioned between the end portion of the optical fiber 42 and the upper surface of the cover layer 38.

In FIG. 19, an optical signal is illustrated as being transmitted and received in a vertical direction through the upper surface of the photonic integrated circuit 32, but embodiments are not limited thereto. For example, the optical connector 40 may be connected toward a side surface of the semiconductor package 100, so that an optical signal may be transmitted and received horizontally through a side surface or edge of the photonic integrated circuit 32. In this case, the photonic integrated circuit 32 may include an edge coupler instead of the grating coupler 455 described above.

In one or more embodiments, the semiconductor package 100 may include a plurality of optical structures 30, and thus may include a plurality of optical connectors 40 optically connected to each of the optical structures 30. The optical connectors 40 may be respectively connected between the optical structures 30 and an external device. A first end of the optical fiber 42 of each of the optical connectors 40 may be optically connected to each of the optical structures 30, and a second end of the optical fiber 42 of each of the optical connectors 40 may be optically connected to an external device.

Through the manufacturing process of FIGS. 13 to 19, the semiconductor package 100 capable of improving an optical communication speed with an external device and reducing signal loss may be formed.

According to one or more embodiments, the communication speed of a semiconductor package communicating with an external device using an optical signal may be improved, and the signal loss may be reduced.

According to one or more embodiments, a size of the semiconductor package may be reduced.

For example, in the semiconductor package, the photonics module may be arranged in parallel to the HBM and vertically to a logic die in a structure where the HBM and logic die are vertically stacked. By vertically connecting the photonics (e.g., the optical module) and the logic die, the signal transmission path is shortened, improving communication speed and minimizing signal loss. Additionally, by vertically arranging the logic die and the photonic modules, the package size may be reduced.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor package comprising:
a substrate;
a logic die on the substrate;
a base insulating layer on side surfaces and an upper surface of the logic die;
an insulating layer through via extending through the base insulating layer at a side of the logic die;
a high bandwidth memory on an upper surface of the base insulating layer;
at least one optical structure on the upper surface of the base insulating layer; and
at least one optical connector comprising an optical fiber configured to transmit an optical signal between the at least one optical structure and an external device,
wherein the high bandwidth memory comprises a plurality of memory dies stacked in a first direction that perpendicular to the upper surface of the base insulating layer, and
wherein the at least one optical structure is connected to the logic die in the first direction.

2. The semiconductor package of claim 1, wherein the at least one optical structure overlaps the logic die and the insulating layer through via in the first direction.

3. The semiconductor package of claim 1, wherein the at least one optical structure comprises:
a photonic integrated circuit on the upper surface of the base insulating layer, and
an electronic integrated circuit on at least a portion of an upper surface of the photonic integrated circuit.

4. The semiconductor package of claim 3, wherein the at least one optical structure further comprises a cover layer covering the upper surface of the photonic integrated circuit and an upper surface of the electron integrated circuit, and
wherein the cover layer comprises a light-transmitting material.

5. The semiconductor package of claim 4, wherein the at least one optical connector is on an upper surface of the cover layer, and
wherein the cover layer is between an end portion of the optical fiber and the upper surface of the photonic integrated circuit.

6. The semiconductor package of claim 5, wherein the photonic integrated circuit comprises a grating coupler optically connected to the optical fiber.

7. The semiconductor package of claim 4, wherein the at least one optical structure comprises a light transmitting insulating layer between the cover layer and the photonic integrated circuit and on a side surface of the electronic integrated circuit.

8. The semiconductor package of claim 1, further comprising a plurality of first connection pads and a plurality of second connection pads on the upper surface of the logic die,
wherein the plurality of first connection pads are connected to the at least one optical structure, and the plurality of second connection pads are connected to the high bandwidth memory.

9. The semiconductor package of claim 1, wherein the at least one optical structure comprises a plurality of optical structures on the upper surface of the base insulating layer;
wherein the at least one optical connector comprises a plurality of optical connectors respectively connected between the plurality of optical structures and the external device,
wherein the plurality of optical structures are arranged in a second direction that is parallel to the upper surface of the base insulating layer.

10. The semiconductor package of claim 1, further comprising:
a thermal conduction pad connected to the insulating layer through via and the logic die in the first direction; and
a thermal conduction block on the thermal conduction pad.

11. The semiconductor package of claim 1, wherein the at least one optical structure comprises:
a photoelectronic integrated circuit on the upper surface of the base insulating layer,
a cover layer covering an upper surface of the photoelectronic integrated circuit, and
a light transmitting insulating layer between the photoelectronic integrated circuit and the cover layer, and
wherein the cover layer and the light transmitting insulating layer comprise a light-transmitting material.

12. The semiconductor package of claim 1, wherein the high bandwidth memory further comprises a base die below the plurality of memory dies, and
wherein the base die comprises a field programmable gate array (FPGA) die.

13. The semiconductor package of claim 1, wherein the high bandwidth memory further comprises a base die below the plurality of the memory dies, and
wherein the base die comprises a cache memory die having a faster data access speed than data access speeds of the plurality of memory dies.

14. The semiconductor package of claim 1, further comprising a first molding member covering a side surface of the at least one optical structure and the upper surface and side surfaces of the high bandwidth memory.

15. The semiconductor package of claim 14, further comprising a second molding member between the side surface of the at least one optical structure and the first molding member.

16. The semiconductor package of claim 14, further comprising an underfill member between a lower surface of the at least one optical structure and the upper surface of the base insulating layer.

17. A semiconductor package comprising:
a substrate;
a logic die on the substrate;
a base insulating layer on side surfaces and an upper surface of the logic die;
an insulating layer through via extending through the base insulating layer at a side of the logic die;
a high bandwidth memory on an upper surface of the base insulating layer;
an optical structure on an upper surface of the base insulating layer; and
an optical connector comprising an optical fiber configured to transmit an optical signal between the optical structure and an external device,
wherein the high bandwidth memory comprises a plurality of memory dies stacked in a first direction that is perpendicular to the upper surface of the base insulating layer,
wherein, in plan view, the optical structure overlaps at least a portion of the logic die, and
wherein the optical structure is connected to the logic die in the first direction.

18. A semiconductor package comprising:
a substrate; and
a plurality of chiplets on the substrate,
wherein each of the plurality of chiplets comprises:
a logic die on the substrate;
a base insulating layer on side surfaces and an upper surface of the logic die;
an insulating layer through via extending through the base insulating layer at a side of the logic die;
a high bandwidth memory on an upper surface of the base insulating layer;
an optical structure on the upper surface of the base insulating layer; and
an optical connector comprising an optical fiber configured to transmit an optical signal between the optical structure and an external device,
wherein the high bandwidth memory comprises a plurality of memory dies stacked in a first direction that is perpendicular to the upper surface of the base insulating layer, and
wherein the optical structure is connected to the logic die in the first direction.

19. The semiconductor package of claim 18, further comprising a bridge layer in an upper portion of the substrate,
wherein the plurality of chiplets are connected together by the bridge layer.

20. The semiconductor package of claim 18, further comprising a redistribution layer between the substrate and the logic die of each of the plurality of chiplets,
wherein the plurality of chiplets are connected together by the redistribution layer.
